(19) United States
(12) Patent Application Publication
(10) Pub. No.: US 2007/0064501 A1
(43) Pub. Date: Mar. 22, 2007

(54) Wavelength-maintaining optical signal regenerator

(76) Inventors: Carsten Bornholdt, Berlin (DE); Bernd Sartorius, Berlin (DE); Juraj Slovak, Berlin (DE)

Correspondence Address: Law Offices of Karl Hormann, PO Box 381516, Cambridge, MA, 02238-1516, US

(21) Appl. No.: 10/571,647

(22) PCT Filed: Sep. 9, 2004
(86) PCT No.: PCT/DE04/02003

§ 371 Date: Mar. 14, 2006

(30) Foreign Application Priority Data
Sep. 19, 2003 (DE) 103 44 319.3

(51) Int. Cl. G11C 7/10

(52) U.S. Cl. 365/189.05

(57) ABSTRACT

The invention relates to a wavelength-maintaining purely optical signal regenerator to which degraded optical signals with a high data rate are transmitted and regenerated without opto-electronic or wavelength conversion using compact, non-linear semiconductor components with low power consumption. Said regenerator comprises: an optical clock regeneration stage (2) which generates synchronized stable optical reset clock pulses for the data signal (1); at least one semiconductor component that is non-linear with reference to the transmission characteristics for the data signal (5,9); means for transmitting part of the degraded data signal (1) to the clock regeneration stage (2) being configured in such a way that a timed optical reset to achieve transparency occurs; a time-slice control unit (3) which is connected upstream of the semiconductor component (5,9) and defines a sequence of data bits in the time gap between two respective clock pulses, means for transmitting the other part of the degraded data signal (1) to the semiconductor component (5,9) at a power at which the semiconductor component (5,9) relaxing from the condition of transparency exhibits a nonlinear transmission characteristic for the data signal, and a blocking unit (6) that is connected downstream of the semiconductor component (5,9) and that removes the reset clock pulses from the data signal path.

The invention relates to a wavelength-maintaining optical signal regenerator.

The regeneration of degraded signals is an important function of optical signal processing. Degradations in digital data signals are amplitude fluctuations of the “1” bits, temporal jitter of the “1” bits as well as noise and interference signals in the time slots of the “0” bits. If all data bits are drawn in superposition the result will be a so-called eye diagram which for purposes of a flawless data recognition must be clearly open.

For an error-free data transmission it is necessary to remove the different degradations in a so-called 3R regenerator (re-amplification, re-timing, re-shaping) by certain function elements, such as, for example, by the “decider”, a threshold switch of a digital switching characteristic, and the “clock regenerator” which generates a stream of synchronized pulses of stable amplitude and clock rate from a degraded data signal. For the regeneration it is necessary that these function elements cooperate regeneratively in an optical circuit.

Because of their compactness and relatively low power consumption non-linear optical semiconductor components are preferably used for realizing the described functions.

As regards the clock regeneration at high data rates (10/40/160 GHz) self-pulsing DFB lasers of different structures have been developed during recent. Thus, high frequency optical clock regenerators are available.

However, semiconductor deciders as well as circuit architectures which require no wavelength conversion are problematic.

The best-known optical semiconductor function element which may be used as a decider is the saturable absorber (SA). Low power signals (e.g. noise at “0” bits) are absorbed by it, but increasing the signal power (e.g. the “1” bits) leads to absorption saturation and fading so that the absorber becomes transparent. In this manner, the absorber can remove the weak disturbances from the data signal. The SA can also be used as an optically controlled switch. A weak constant signal of a different wavelength input in addition to a strong data signal or clock pulses synchronized with the data bits are transmitted or blocked dependent upon the “1” or “0” bits in the data signal, so that, at a suitable switching characteristic with a threshold value, the data information is regeneratively superposed upon the new carrier wavelength.

The semiconductor optical amplifier (SOA) is another non-linear function element which is frequently used. Input signals of low power are linearly amplified, but the input of more powerful signals leads to a saturation output power, i.e. the amplification is becoming increasingly smaller so that the amplification of another weaker signal of a different wavelength may be affected (cross amplification modulation which is often used for wavelength conversion). However, a regenerative switching characteristic is not attained until the SOA is included in an interferometric arrangement and the changes in refractive index associated with the amplification and charge carrier density modulations may thus be made use of.

In rapid signal processing, the time characteristic of the semiconductor optical function elements is problematic since they make use of the change of charge carrier density affected in the conduction band or valence band of the semiconductor. While upon input of a data pulse and its absorption or amplification, the charge carrier density responds to the optical signal with practically no lag (faster than fs), but upon decay of the optical signal the charge carrier density relaxes substantially more slowly, i.e. at the time constants of the free semiconductor in the nano-second range. The effect of this behavior is particularly critical where data patterns have to be processed. Test sequences in telecommunication contain sequences of alternating “0” and “1” bits as well as series of up to thirty-one consecutive identical bits. Any expert is familiar with the fact that, beginning at a 10 Gb/s data signal between bits, no absorber relaxes sufficiently to its state of equilibrium and thus suffers from strong data pattern effects. Following a “0” bit sequence the SA, upon arrival of a “1” bit opens with a time delay and not totally, and between to consecutive “1” bits no substantial absorption is attained. Compared to the incoming data signal the switching curve of the SA is degraded; hence, the component cannot be used for regeneration.

The fact that the non-linear characteristic is strongly dependent upon its prior history, holds true also for the SOA. A data pulse after a long “0” sequence impinges upon a “recovered” unsaturated SOA and is correspondingly strongly amplified, whereas a data pulse after a long “1” bit sequence impinges on a saturated SOA and is thus amplified only insignificantly.

Thus, their data pattern dependency acts disadvantageously on the two described semiconductor function elements.

In the prior art of hitherto known regenerators the data signal energizes, at high energy, a non-linear dicer element (based, e.g., on saturable absorbers or semiconductor amplifiers integrated into interferometers) which acts as a transmission/blocking switch and which transmits the data information to a clock signal of different wave length which also penetrates the semiconductor. It is necessary that the decider element have a stepped switching characteristic with a decision threshold as to the input level and a high switching contrast between “0” and “1” bits for the output signals, and this function must be ensured even at high data rates and independently of data patterns. For that reason, considerable efforts are being made to develop semiconductor materials with faster time constants (ECOC 200, Munich, invited paper We 9.4.1, Conf. Dig. We pp. 293-296).

In a further development of the above method (see, for instance, DE 101 18 959 A1 and ECOC 2002, C. Bornhold, J. Slovak and B. Sartorius: “Novel 3R Regenerator Concept Demonstrated at 40 Gb/s”, ECOC 2002, post deadline paper PD 4.8, Copenhagen, Denmark, 2002) data and clock signal (delayed by half a bit relative to each other) energize the decider element and transmit the data information to a constant signal of a different wavelength which is also being input. The requirements as regards the decider correspond to the ones referred to above. The advantage of this solution is the flexibility of choice as regards the output wavelength independently of the wavelength of the clock pulse.

Another method known in the prior art is operating without wavelength conversion (described by O. Leclerc et al. in “Regenerated 40 Gb/s Long-Haul Transmission Using All-Optical SOA-MZI as Loss-Free Synchronous Modulator”, Paper WF6-1 in Technical Digest of Optical Fibre Communications Conference OFC 2001, Anaheim, Calif., USA, Mar. 17-22, 2001). In a first regenerator step the pulse compression in non-linear glass fibers is used at very high power levels (Soliton effect, pulse of high power is compressed more strongly) for a decider threshold and spectral filtering is used for amplitude equalization (pulse compression leads to spectral spreading, too high a power is trimmed by spectral filters). The temporal jitter is improved in a second stage by a so-called “synchronous modulation”. In this context, the clock pulses periodically energize a modulator by which the data pulse extensions outside of the modulation window are being cut off which causes the data pulse to be shifted in the direction of its correct position in time. The non-linear effects in the glass fiber are so fast that data pattern problems do not arise in this solution. However, the pulse compression requires signal amplification to very high powers and great lengths of the non-linear fiber.

Proceeding from the described prior art, it is thus an object of the invention to provide a wavelength-maintaining and entirely optical signal regenerator into which degraded optical signals of high data rate may be input for regeneration without opto-electronic conversion and without wavelength conversion at low power consumption using compact non-linear semiconductor components.

In accordance with the invention the object is accomplished by a wavelength-maintaining optical signal regenerator provided with
an optical clock regenerator stage which generates stable optical reset clock pulses synchronized with respect to the data signal in amplitude, clock pulse and time slot; and
at least one semiconductor component which relative to the transmission characteristic is non-linear for the data signal; as well as
means inputting a part of the degraded data signal into the optical clock regeneration stage, and
means for inputting the optical clock pulses generated in the clock regeneration stage into the non-linear semiconductor component, the clock regeneration stage being structured such that the gained optical clock pulses are of a wave length ensuring an optical energization of the semiconductor component and of a power sufficient to switch the semiconductor component to a state of transparency such that in the state of transparency a clocked “optical reset” is attained,
a time slot setting unit at the input of the semiconductor component for providing a sequence of data bits in the time gap between each of two reset clock pulses,
means for inputting the other part of the degraded data signal into the semiconductor component at such power at which the semiconductor component relaxing from its transparency has a non-linear transmission characteristic for the data signal, and
a blocking unit downstream of the semiconductor component which removes the optical rest clock pulses from the data signal stream, the reset clock pulses differing from the data signal in the beam direction, wavelength or polarization.

Where technical necessities require that power of the data and/or clock signal be set, one embodiment of the invention provides for at least one power setting unit at the input of the semiconductor component.

The following embodiments relate to the non-linear semiconductor component.

Thus, on the one hand, for removing noise and interference signals at “0” bits, it is a saturated absorber (SA), and the data signal is of such power that the power of the interference signals at “0” bits is slightly below the absorption capacity of the saturable absorber relaxing from its transparency, whereas the power of the “1” bits clearly exceeds the absorption capacity of the relaxing saturable absorber.

On the other hand, the non-linear semiconductor component is a semiconductor amplifier (SOA) for regenerating the amplitude of the “1” bits (equalizer function). Where the data signal is input into the non-linear SOA relaxing from its transparency at such an input power that the “1” bits lead to saturation power at the output, the amplitude fluctuations of the “1” bits are blocked by the power saturation and a desired “equalizer effect” will be achieved.

The regenerator for blocking amplitude fluctuations may be expanded by simple means to a regenerator for pulse shaping (re-shaping) and for the time slot (re-timing). For this purpose, the shape of the clock pulses is of importance. If necessary, they may be set by means at the output of the clock regeneration stage such that the shape of the gap between the clock pulses, of inverse power, corresponds to the desired shape of the output pulses.

The solution in accordance with the invention is based on the fact that it is not only the relaxed system which represents a defined state without optical signal but also the saturated semiconductor driven into transparency by a strong optical signal. The saturated transparent absorber will have a charge carrier density in its band which at the signal wavelength has a population probability of ½. According to physical basic principles (Einstein coefficient) this value cannot be increased even by any increase of input light power (absorption=amplification, net balance zero, transparency). By inputting a strong signal a defined state (transparency) is set in a saturated absorber, regardless of the prior history of the absorber and regardless of the power of the signal. It is to be noted that the ideal theoretical transparency condition (population probability=½) can be only be reached asymptotically at an infinitely high power, just like a temporal decay after an interference reaches the ideal equilibrium asymptotically only after an infinitely long time. The attainment of these ideal theoretical threshold values is not necessary for practical applications. In practical applications an approach to the point of equilibrium is sufficient such that the prior history no longer affects the processing of the next following signal in any substantial manner. “State of transparency” as used hereafter refers to this practical characteristic. In the solution in accordance with the invention, the state of transparency defined in this manner is attained as follows: The time slot setting unit at the input of the semiconductor component, e.g. the saturable absorber (SA), and the clock generation stage which generates a stream of synchronized reset clock pulses which is stable in terms of amplitude, clock pulse and time slot, inject, chronologically controlled, a data pulse of a suitable wavelength (above the band edge) and sufficient power between each of two reset pulses. The data pulses are thus injected into the semiconductor in a chronologically controlled manner. Since, as has been described before, the semiconductor follows an increasing optical signal at high speed, an ultra-fast optical reset to the defined state of transparency is attained. The effect of the prior history is blocked by differently powered absorption/transmission of the reset pulses. An advantage of the periodic resetting in the solution in accordance with the invention resides in the prior history consists of only a single bit which may be either “1” or “0”. Thus, the compensation of the prior history is thus simpler than the compensation of long “1” and “0” sequences.

The same physical bases apply to the amplification saturation of an semiconductor optical amplifier (SOA) as to an SA; here, too, proceeding in this case from a higher charge carrier density (population>½, amplification), input of a strong optical signal leads to attaining the ½ population probability. It is to be noted that the expression amplification saturation is describing the non-linear range of the amplifier, but that to date no term of art has been coined for the state of transparency of an amplifier. Even at an arbitrary increase of the optically input power it is not possible to go below the population value of ½ and its appurtenant charge carrier density. Therefore, a SOA will be put into the defined state of transparency by a sufficiently strong optical reset pulse of suitable wavelength (in the amplification spectrum), regardless of its prior history. The effect of the prior history is blocked by the different amplification of the (no longer required) reset pulses.

The first function block of the regenerator in accordance with the invention, i.e. the optical clock regeneration stage, into which a part of the degraded data signal is input and which may, for instance, be provided with a self-pulsing DFB laser, sets a stream of synchronized clock pulses. The other part of the degraded data signal enters into the second function block consisting of a semiconductor of optically non-linear transmission characteristics as to the data signal (SA, SOA). The clock pulses generated in the first function block are also input into the function block “non-linear semiconductor” but at a wave length, beam direction or polarization distinguishable from the data signal so that data and clock pulses can be separated after the regenerator. The wavelength of the clock pulses is selected so that the semiconductor (by absorption or amplification) may be energized by it (photon energy above the band edge). A first decisive point in this context is to set the power of the clock signal to ensure that the clock pulses drive the semiconductor into the defined state of transparency (½ population probability at the clock wave length) and thus to ensure a clocked optical reset. A second decisive measure, i.e. to insert the data pulses into the semiconductor with a delay after a reset pulse, that is to say into the gap between two reset pulses, is being realized by a suitable delay line. The power of the data signal is now set so that the data signal is regeneratively shaped by the semiconductor relaxed from its defined state of transparency by way of the non-linear transmission characteristic thereof.

In another embodiment of the invention the non-linear semiconductor amplifier is structured as a multi-section component with separate electrical contacts. Thus, the power level for the regeneration in a succeeding second non-linear section may be electrically set and adjusted in a first amplifying section. Furthermore, the semiconductor amplifier may be realized in the material systems InP or GaAs or AlAs. In an advantageous embodiment the non-linear semiconductor components are monolithically integrated on a semiconductor disc or integrated in a hybrid manner on a passive waveguide material.

The clock regeneration stage may be provided with a self-pulsing or with a mode-coupled laser.

The following embodiments of the invention relate to the saturable absorber. It is structured as a thin layer into which irradiation takes place in a vertical direction. Where this absorber layer is to be used simultaneously for several regenerators it will be energized in parallel by several signals at different sites. For instance, the layer may be penetrated by several signal's at several adjacent points, e.g. in a wavelength multiplex system. However, the saturable absorber may also be formed in a wave guiding structure. Preferably, the thin absorber layer is provided with electrical contacts for setting its absorption characteristic. The saturation characteristic may be electrically set by applying a voltage or by injecting a current.

Where it is necessary to realize a complete 3R regenerator which not only eliminates noise and interference signals at the “0” bits but which also prevents amplitude fluctuations, the invention provides for a cascading arrangement of a saturable absorber and a semiconductor amplifier in the non-linear semiconductor component. In this manner, the solution in accordance with the invention may be flexibly structured and may be used for different purposes.

In one embodiment of the invention a pulse shaping unit is disposed at the output of the clock pulse regeneration stage for shaping the optical clock pulses such that their power inverted shape corresponds exactly to the desired shape of the data pulses.

Depending upon the characteristics of the data and clock signal, the blocking unit for removing the optical reset pulses from the stream of data is a wavelength or polarization or geometric space filter.

The inventive solution or preventing data pattern effects by clocked reset pulses is basically distinguished from wavelength converting methods in which the data signal energizes the non-linear semiconductor to open or close it as a transmission switch in accordance with “1” or “0” bits to transmit the data to a clock signal or to a constant signal of a different wavelength. The inventive solution utilizes the direct non-linear action of the semiconductor on the signal in order to regenerate it directly without any wavelength conversion. The regeneration with respect to different degradations to “1” or “0” bits takes place in separate stages which may also be used individually, but which—as has been set forth—are also fully integrated to a complete 3R regenerator. For suitable requirements and certain applications it may also be useful to combine the regenerators in accordance with the invention with wavelength conversion techniques.

With certain semiconductor materials and time constants the solution in accordance with the invention eliminates the data pattern dependency at high data rates and provides arrangements for realizing different required regeneration functions (amplitude equalization, set of time slots and noise signal suppression) without any need for a wavelength conversion. There is no need for a high switching contrast (as required for full transmission/blocking functions of prior art solutions), but even weak non-linear transmissions may be utilized.

Other advantageous embodiments of the invention have been set forth in the sub-claims or they will hereafter be described in greater detail in the description of embodiments of the invention with reference to the drawings, in which:

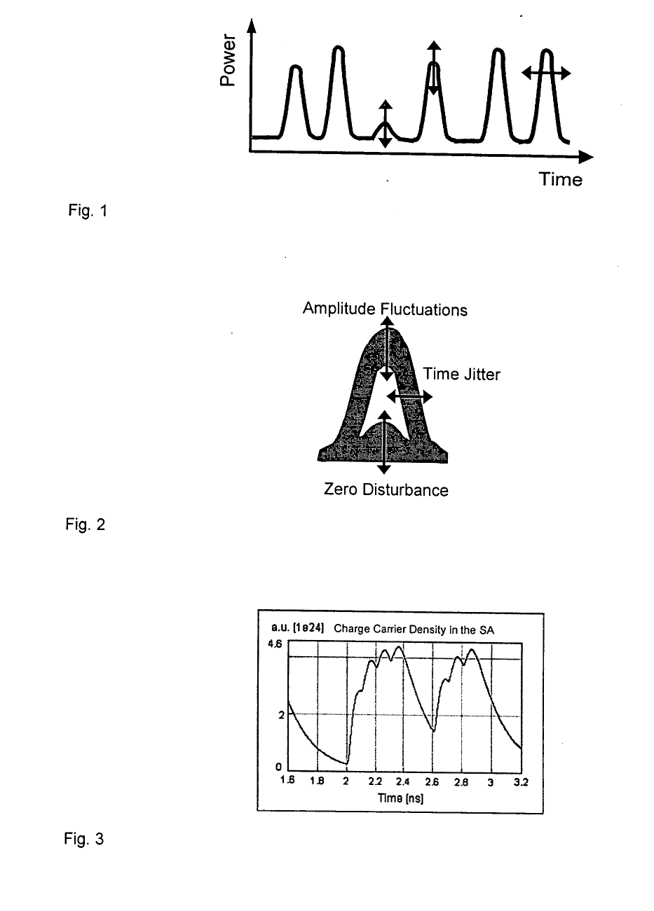

FIG. 1 schematically depicts degraded data signals as a pulse train;

FIG. 2 schematically depicts degraded data signals as an eye diagram;

FIG. 3 depicts model calculations for the charge carrier density relating to a SA energized in conventional operation at 10 Gb/s data signals;

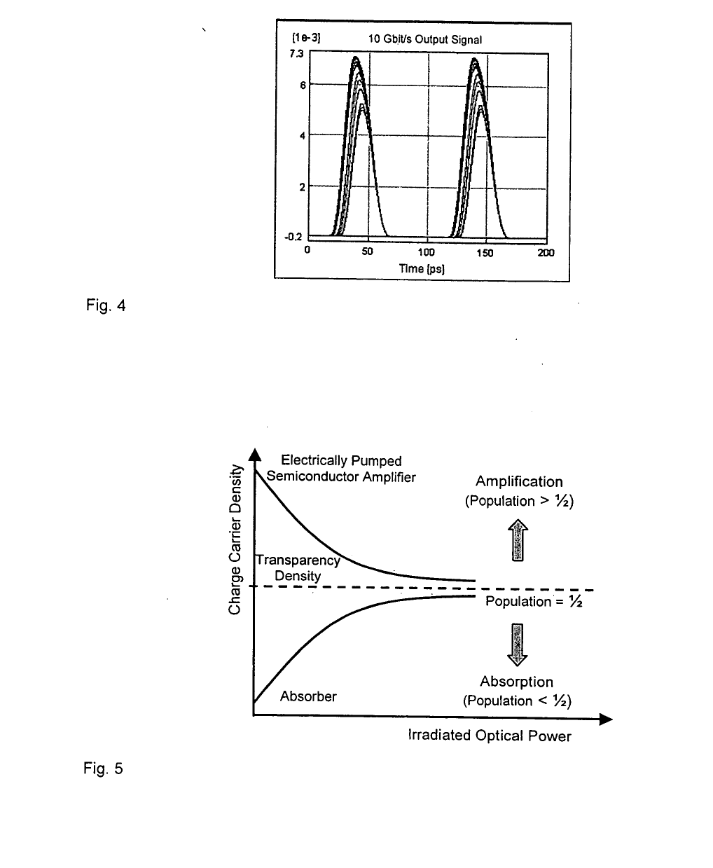

FIG. 4 depicts model calculations for the transmission characteristic of an SA energized in conventional operation at 10 Gb/s data signals;

FIG. 5 schematically shows the dependency of the charge carrier density from the power of the input clock signal for a SA and a SOA;

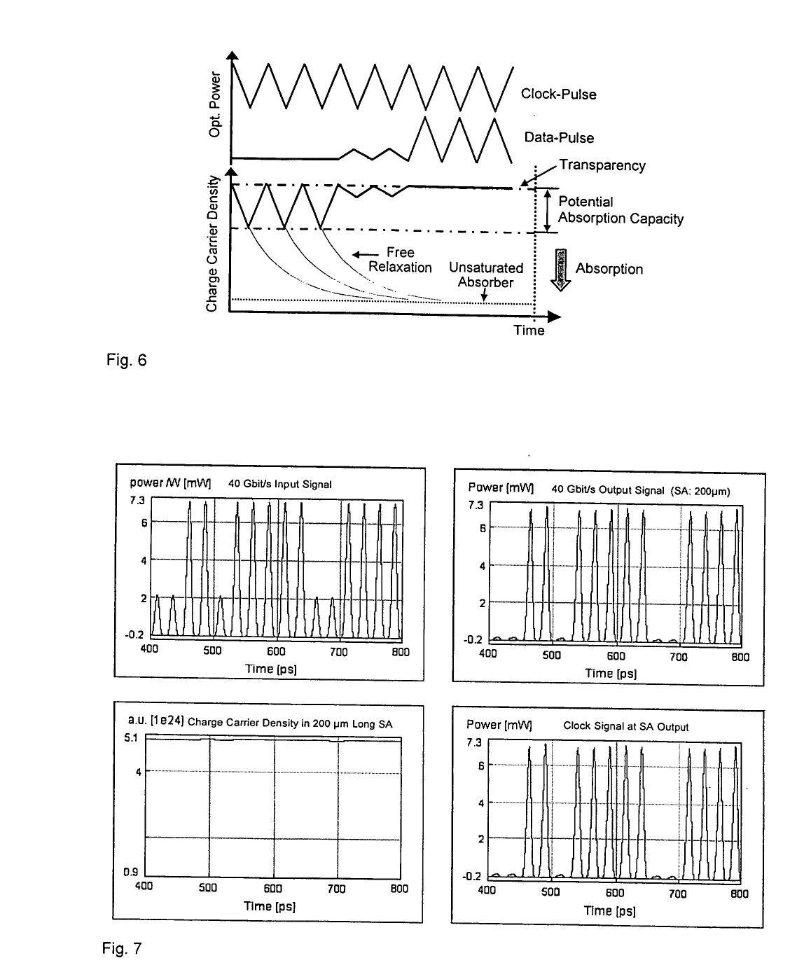

FIG. 6 schematically depicts the dependency of the charge carrier density of a SA when energized by clocked optical reset;

FIG. 7 depicts a model calculation relative to a SA according to FIGS. 3 and 4 but energized by clocked optical reset;

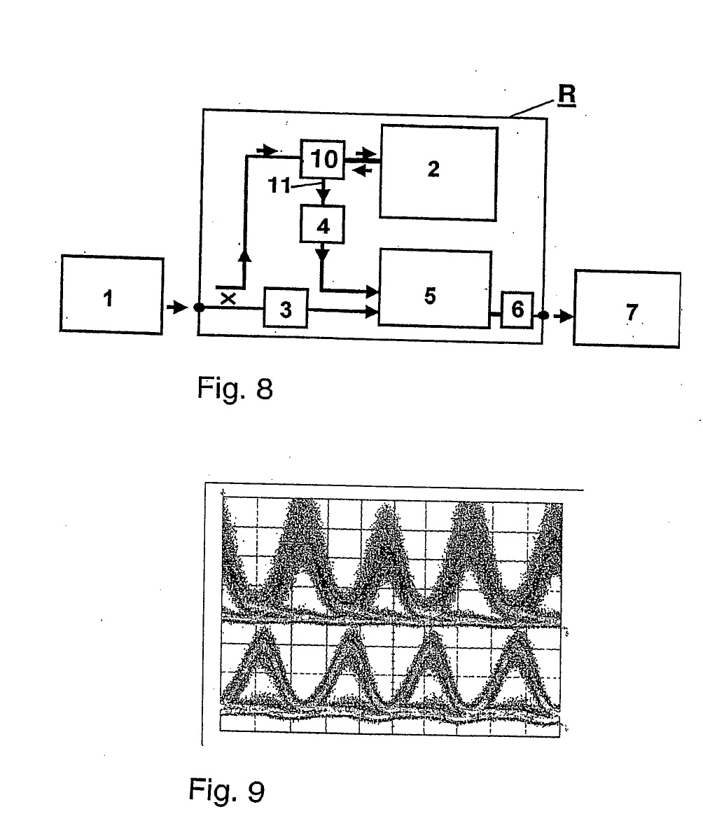

FIG. 8 schematically depicts a regenerator in accordance with the invention with a non-linear SOA;

FIG. 9 depicts eye diagrams (input/output) of a regenerator in accordance with FIG. 8;

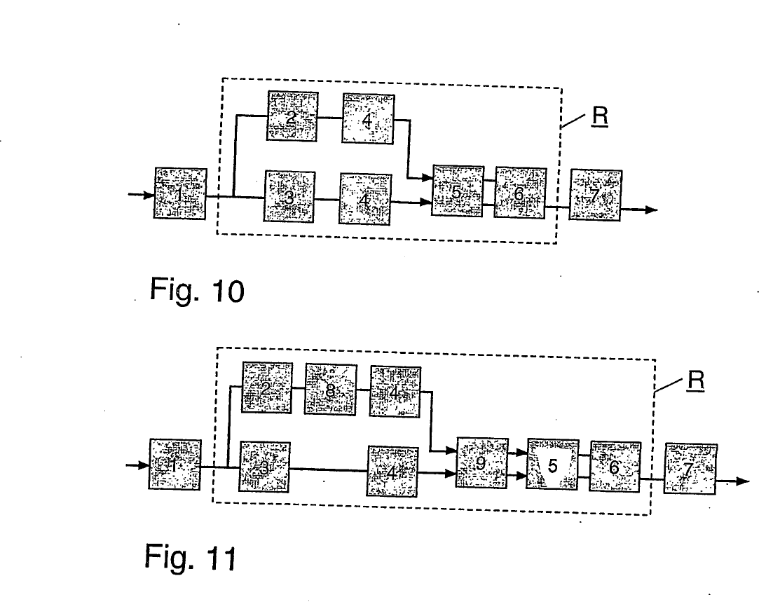

FIG. 10 is a block circuit diagram of a regenerator in accordance with FIG. 8;

FIG. 11 is a block circuit diagram of an SOA and an SA in a cascading arrangement.

FIG. 1 depicts degraded data signals (interference signals at “0” bits, amplitude fluctuation of “1” bits and time jitter of the “1” bits) as a pulse train. FIG. 2 depicts them as an eye diagram in which all data bits are drawn in periodic superposition. For a flawless recognition of data the eye diagram must be clearly open.

FIG. 3 depicts the result of a model calculation of a charge carrier density modulation for a SA energized at 10 Gb/s in a conventional operation. FIG. 4 depicts a model calculation of the transmission characteristic (eye diagram). The data pattern dependency may still be clearly recognized. In such a known SA the absorber does not sufficiently relax to a state of equilibrium even at this data rate between the bits and thus display very strong data pattern effects. After a “0” sequence the SA opens with a delay and incompletely upon arrival of a “1” bit. Compared to the energizing data signal the switching curve of the SA is, therefore, degraded, which is why the component cannot be used for regeneration.

FIG. 5 depicts the progress of the charge carrier density as a function of the input optical power. As has already been mentioned, it is the aim of the solution in accordance with the invention to eliminate the data pattern dependency.

Use is thus made of the recognition that it is not only the relaxed system without any optical signal which represents a defined state but that the semiconductor saturated by a strong optical signal represents one as well. As has already been mentioned, a defined state, i.e. transparency, is set (absorption=amplification, net balance zero, transparency) by inputting a sufficiently strong signal into a SA. This is taking place independently of the prior history of the SA and independently of the power of the signal. The same holds true for a SOA: Here, too, inputting a strong optical signal leads to attainment of the ½ population probability (proceeding in this case from a higher charge carrier density−population>½, amplification). Even at an arbitrary increase of the optically input power it is not possible to go below the ½ population value and the corresponding charge carrier density.

FIG. 6 schematically depicts the progress of the charge carrier density of a absorber in an optical signal regenerator in accordance with the invention when energized by a clocked optical reset. Chronologically controlled by the clock regeneration and a delay line, a reset pulse of suitable wavelength (energetically above the band edge) and sufficient power is inserted into the non-linear semiconductor component between every two data pulses. The semiconductor component in this case is a SA. As has already been described, the semiconductor component follows an increasing optical signal at high speed. In this manner, as can be seen, an ultra-fast optical reset into the state of transparency is attained. In the solution in accordance with the invention, the prior history is blocked and reduced to but a single bit, either “1” or “2”.

Hereafter, the regenerative function of an optical signal regenerator in accordance with the invention including as a semiconductor component a saturable absorber (SA) or a semiconductor amplifier (SOA) will be explained in connection with the types of degradation
noise and interference at the “0” bits,
amplitude fluctuations of the “1” bits and
time jitter of the “1” bits.

The semiconductor required for the elimination of noise and interference signals at the “0” bits is a SA. The SA is driven to the defined state of “saturation” by the clock pulses, independently of the prior history of the absorber. The prior history of the absorber only affects the transmitted power of the—no longer required—clock pulses. Every data bit succeeding the clock pulse thus sees a relaxing saturable absorber of the same characteristic (optical reset function) which looks as follows:

After the decay of the optical reset pulse the saturable absorber relaxes—as is known—in the direction of a high absorption. The absolute change of transmission per unit time, in the time interval directly following the switching off of the exterior signal, is greater than during the further course of decay. This is shown in FIG. 6. At a given dynamic (determined by the material of the SA and its time constant) the saturable absorber and the change of absorption is, therefore, used most effectively at the reset working point selected in this context.

If, therefore, a “0” bit with interference penetrates the absorber during the rapid increase of absorption after the reset pulse, the small interference signals are absorbed and the increase of the absorption is slowed down. If a strong “1” pulse penetrates the absorber as many photons will be taken away from it as are necessary for maintaining its saturation or transparency, as the case may be. In this connection it is important that in the saturated absorber the number of removed photons is not proportional to the input power, but that it is a set number predetermined by the characteristics of the absorber or adjustable (e.g. length).

Hence, the saturated absorber removes same number of photons from a “1” bit as from the interference signals of a “0” bit. The identical photon subtraction means that the small interference signals at the position of the “0” -bits are weakened less than the large “1” bits. The signal-to-noise-ratio is thus increased by this photon subtraction and the quality of the signal relative to this parameter is improved. The photon subtraction is defined exactly as a result of the clocked reset. It is to be emphasized that the function not depending on data patterns at high data rates is attained by the solution in accordance with the invention without any need for increasing the relaxing times of the absorber. The absorber must only be set by its specific saturation characteristic and its length so that the number of photons required for maintaining the saturation corresponds to the number of the expected interference photons in the “0” bits.

This behavior is confirmed by model calculations (commercial program by VPI Company). FIG. 7 presents the results of this model calculations regarding the behavior of a saturable absorber with an optically clocked reset. The identical absorber which in normal operation at 10 Gb/s already brought about strong data pattern effects (see FIG. 3), in an optically clocked reset operation functions regeneratively even at 40 Gb/s. By way of comparison, the figure also shows the data signal with interferences at the “0” bits input into the signal regenerator, and the output signal. The charge carrier density is almost constant in the SA as may be seen in the third partial image. Only small charge carrier density modulations are occurring but the interference signals at the “0” bits are cut off. This demonstrates that the data pattern effects—as may be seen in the fourth partial image—are successfully blocked and that the functional speed at the given material has been increased considerably. Even the 40 Gb/s do not constitute the limit of the speed.

The semiconductor required for blocking the amplitude fluctuations at the “1” bits is a SOA. As has already been described, the SOA is driven into its defined state of “transparency”, independently of the prior history of the SOA. Each data bit succeeding the clock pulse therefore sees a non-linear SOA relaxing from its transparency. It is known that in the range of the saturation output line any further increase of the input signal does not lead to a further increase in the output power. If the data signal is inserted into the SOA relaxing from its transparency at such an input power that the “1” bits lead to a saturation power at the output, the amplitude fluctuations of the “1” bits will be blocked by the power saturation and a desirable equalizer effect is attained. It is to be mentioned that without the rest pulses, the SOA would amplify the first “1” bit after a long “0” bit sequence substantially higher then any following bits. That is to say that instead of a regenerative equalizer effect data pattern dependent amplitude fluctuations would be generated and the signal would be degraded. The reset pulses are decisive for a regenerative effect.

The regenerator in accordance with the invention for blocking amplitude fluctuations may very easily be broadened into a generator for pulse shaping (re-shaping) and the temporal pulse position (re-timing). For this purpose, the shape of the clock pulses is important which, if necessary, are set by pulse shaping means downstream of clock regeneration stage such that the shape of the gap between clock pulses, inverted in power, corresponds to the desired output pulse shape.

The amplification of the SOA will recover between the clocked reset pulses. A data pulse is shaped in accordance with the temporal change of amplification: The amplification will be higher in the gap between the reset pulses. Here, the data pulse is amplified more, whereas the amplification is less in the flanks of the reset pulse; the data pulse is trimmed here. A pulse shaping results here by the flanks of the rest pulse (re-shaping) and a temporal centering of the data pulses in the center of the reset pulse gap (re-timing). If data pulses of a certain shape or length are wanted, the rest pulse may be adjusted in accordance with the requirements in the mentioned pulse shaping stage.

The pulse shaping and the pulse clocking correction in accordance with the above principle has a very high speed potential. For that reason consideration has to be given to the fact that aside from the very effective but relatively slow (range 10 GHz) amplification modulation by change of the integrated charge carrier density in the SOA (intra band) there also exists the effect of the “spectral hole burner”. In this connection, the distribution of the spectral charge carrier density within a band of the SOA (intra band) is affected by a strong signal and the amplification is thus modulated in the range of up to several 10 μm away from the signal. This effect offers the great advantage of a very high speed potential up to the THz range, as well as the disadvantage of a substantially less effective amplification modulation. The fast intra-band effect may thus only be used if data pattern effects are prevented because of the stronger and slower inter-band effect. In the proposed arrangement, the effects of the data pattern on the charge carrier density is compensated (transmitted to the reset pulses). The amplification modulation by the fast intra-band effect which transmits the inverse pulse shape of the reset pulses to the data pulses and thus takes care of re-shaping and re-timing at high data rates, does remain. Such a regenerator of amplitude equalization, re-timing and re-shaping and experimental results are described in the following embodiment.

FIG. 8 depicts such a signal regenerator in accordance with the invention. A degraded signal 1 of a wave and a pseudo random bit sequence (PRBS) at a data rate of 40 Gb/s is injected by means of a glass fiber into the regenerator R. It is there split into two parts by a 3 dB coupler. For clock regeneration, one of the signal parts is injected by way of a circulator 10 into a pulse regenerator stage 2 which may be provided, for instance, with a DFB laser. In this manner the pulses emitted by the self-pulsing laser are synchronized with respect to the data signal. The synchronized clock pulses 11 (wavelength 1,560 nm) obtained at the output of the circulator 10 and which are shaped sinusoidally and the power-inverted shape corresponds to the desired shape of the output pulses are amplified by a linear optical semiconductor amplifier to a power of 8 dBm and are then injected into a non-linear semiconductor amplifier of a length of 2 mm (realized in the material system InGaAsP and with an amplification spectrum in the range of 1,500 nm to 1,600 nm). Owing to the length of the non-linear semiconductor amplifier 5 and to its selected input power the non-linear semiconductor amplifier 5 is initially driven into its defined state of transparency (clocked optical reset) and the amplification is then modulated in the rhythm and shape of the clock pulses by intra-band effects (spectral hole burning).

The other part of the data signal 1 is also injected into the non-linear semiconductor amplifier 5 (in the same beam direction as the reset pulses but at a different wavelength). The time slot of the data pulses is set by a delay line 3 such that they reach and penetrate the non-linear semiconductor amplifier 5 in the exact center between two rest clock pulses. Behind the non-linear semiconductor amplifier 5 there is provided a blocking unit, such as, for instance, a wavelength filter, which only transmits the wavelength of the desired data signal 7 (here 1,552 nm) while blocking the wavelength of the optical reset signal (here 1,560). In this embodiment, the signal passes through the regenerator R without any opto-electronic change and without wavelength conversion. In the regenerator, a semiconductor amplifier clocked by an optical reset signal and of a length sufficient for the desired non-linear effect is permeated by the signal.

FIG. 9 depicts the eye diagrams of the degraded 40 Gb/s data signal injected into the regenerator schematically shown in FIG. 8 and of the output signal. It can be seen at the wide track at the maximum that substantial amplitude fluctuations occur; substantial time jitter may be seen at the temporal width of the upward flanks. The output signal generated after passing the signal regenerator in accordance with the invention depicts a track which in both ranges is much clearer and much narrower. The amplitude fluctuations have been balanced by the equalizer effect during saturation of the amplifier, and the rapid intra-band amplification modulation of the clock pulses has imposed their sinusoidal profile upon the data signal and has in his manner brought about the desired pulse shaping and time slot positioning.

The function of this regenerator at 40 Gb/s has thus been experimentally proven.

The following two figures represent block circuit diagrams for embodiments of the invention.

Thus, FIG. 10 schematically depicts as a block circuit diagram the arrangement of an optical signal regenerator shown in FIG. 8. As has already been described, the degraded data signal 1 is fed into the regenerator R. The regenerator R includes a clock regeneration stage 2 provided, for instance, with a DFB laser, into which a part of the degraded data signal is injected and regenerated into a stream of synchronized pulses which are stable as regards their amplitude, time pulse and time slot. These clock pulses are led to the non-linear semiconductor amplifier 5 by way of the amplifier unit 4, as is the other part of the data signal 1, which by way of an amplification unit 4 is also directly fed into the non-linear semiconductor amplifier 5. At the output of the non-linear semiconductor amplifier 5 there is provided a blocking unit 6 for the optical reset pulses. In this embodiment of the invention, regenerated data signals 7 are furnished at the output of the regenerator.

As has already been mentioned, the solution in accordance with the invention is flexible in the way it may be practiced as it may include further means necessary for its application. FIG. 11 depicts a block circuit diagram depicting a cascading arrangement of blocks previously described individually. Thus, this arrangement includes, aside from components mentioned above, an additional non-linear semiconductor component, i.e. a saturable absorber 9. The partial data streams are fed into it which in part are processed in the clock regeneration stage 2, a pulse shaping unit 8 downstream thereof and a downstream power setting unit 4, and which in part are processed in a time setting unit 3 and a further power setting unit 4. In this case, the non-linear semiconductor amplifier 5 is arranged downstream of the saturable absorber 9. A blocking unit 6 is provided for filtering out the optical reset pulses generated in the clock regeneration stage. In the cascading arrangement of saturable absorber 9 and non-linear semiconductor amplifier 5 the clock regeneration stage 2 is arranged as a common stage upstream of the two non-linear semiconductor components 5, 9. In the data signals 7 at the output of the complete 3R regenerator R noise and interference signals have been eliminated and amplitude fluctuation has been prevented.

1. A wavelength-maintaining optical signal regenerator, comprising:
an optical clock regeneration stage (2) for generating optical reset clock pulses synchronized with respect to the data signal (1) and stable in amplitude, clock pulse and time slot, and
at least one semiconductor component (5,9) non-linear with respect to the transmission characteristic of the data signal as well as
means for injecting apart of a degraded data signal (1) into the optical clock regeneration stage (2) and
means for injecting the optical clock pulses generated in the clock regeneration stage (2) into the non-linear semiconductor component (5,9) the clock regeneration stage (5,9) being structured such that the generated optical clock pulses are of a wavelength ensuring optical energization of the semiconductor stage (5,9) and of a power switching the semiconductor component (5,9) to a state of transparency such that a clocked “optical reset” is attained,
a time slot setting unit (3) upstream of the semiconductor component (5,9) which provides a sequence of data bits into the temporal gap between every two reset clock pulses,
means for injecting the other part of the degraded data signal (1) into the semiconductor component (5,9) at such power at which the semiconductor component (5,9) relaxing from the transparency has a nonlinear transmission characteristic for the data signal, and
a blocking unit (6) downstream of the semiconductor component (5,9) which removes the optical reset clock pulses from the data signal beam, the reset clock signals being different from the beam direction, wavelength or polarization of the data signal.

2. The signal regenerator of claim 1,
in which at least one power setting unit (4) is provided upstream of the semiconductor component for setting the power of data and/or pulse signal.

3. The signal regenerator of claim 1,
in which the nonlinear semiconductor component is a saturable absorber (9) and the data signal is of such power that the power of the interference signals at “0” bits is somewhat lower than the absorption capacity of the saturable absorber (9) relaxing from its transparency, whereas the power of the “1” bits clearly exceeds the absorption capacity of the relaxing saturable absorber (9).

4. The signal regenerator of claim 1,
wherein the nonlinear semiconductor component is a semiconductor amplifier (5) and wherein the data signal is of such power that amplitude fluctuations at the “1” bits are set to an equal output amplitude by the nonlinear semiconductor amplifier (5) relaxing from the transparency.

5. The signal regenerator of claim 1,
in which a pulse shaping unit (8) is provided downstream of the clock regeneration stage (2) for shaping the optical clock pulses such that their power-inverted shape substantially corresponds to the desired data pulse shape.

6. The signal regenerator of claim 1,
wherein the nonlinear semiconductor amplifier is structured as a multi-section component.

7. The signal regenerator of claim 1,
wherein the clock regeneration stage (2) is provided with a self-pulsing laser.

8. The signal regenerator of claim 1,
wherein the clock regeneration stage (2) is provided with a mode-coupled laser.

9. The signal regenerator of claim 3,
wherein the saturable absorber (3) relaxing from transparency is structured as a thin layer which in vertically irradiated.

10. The signal regenerator of claim 9,
in which the thin layer is energized in parallel at different sites by several signals.

11. The signal regenerator of claim 3,
wherein the saturable absorber (9) relaxing from transparency is formed in a wave guiding structure.

12. The signal regenerator of claim 3,
in which the saturable absorber (9) relaxing from transparency is provided with electrical contacts for setting the absorption characteristic.

13. The signal regenerator of claim 4,
wherein the semiconductor amplifier (5) is realized in the material systems of InP or GaAs or AlAs.

14. The signal regenerator of claim 1,
wherein a saturable absorber (5) relaxing from transparency and a semiconductor amplifier (5) are arranged in a cascade.

15. The signal regenerator of claim 14,
wherein the nonlinear semiconductor components (5,9) are monolithically integrated on a semiconductor disc.

16. The signal regenerator of claim 14,
wherein the non-linear semiconductor components (5,9) are integrated in a hybrid manner on a passive waveguide material.

17. The signal regenerator of claim 1,
wherein the blocking unit (6) is a wavelength filter.

18. The signal regenerator of claim 1,
wherein the blocking unit (6) is a polarizing filter.

19. The signal regenerator of claim 1,
wherein the blocking unit (6) is a geometric space filter.
